(19) United States
(12) Patent Application Publication
(10) Pub. No.: US 2010/0212284 A1
(43) Pub. Date: Aug. 26, 2010

(54) ION THRUSTER GRIDS AND METHODS FOR MAKING

(75) Inventor: Russell Doerner, Poway, CA (US)

Correspondence Address: GREER, BURNS & CRAIN, 300 S WACKER DR, 25TH FLOOR, CHICAGO, IL, 60606, US

(73) Assignee: THE REGENTS OF THE UNIVERSITY OF CALIFORNIA, Oakland, CA (US)

(21) Appl. No.: 12/521,889

(22) PCT Filed: Sep. 11, 2003
(86) PCT No.: PCT/US2003/028289

§ 371 Date: Jul. 28, 2009

Related U.S. Application Data
(60) Provisional application No. 60/409,863, filed on Sep. 11, 2002.

(51) Int. Cl. F03H 1/00; H05H 1/24; B23P 17/00; C23C 16/44

(52) U.S. Cl. 60/202; 427/569; 29/890.01

(57) ABSTRACT

An ion thruster includes an accelerator grid proximate to an ionization chamber for drawing and accelerating ions from the chamber. The accelerator grid include a core and an overlying layer that is made of a material having a mass less than that of the propellant.

### TECHNICAL FIELD

A field of the invention is ion thrusters. Another field of the invention is vehicle propulsion, e.g., propulsion of spacecraft.

### BACKGROUND OF THE ART

Ion thrusters include a chamber in which propellant is ionized and a negatively charged accelerator grid that promotes a flow of ions out of the chamber. Ion thrusters may use any of a number of suitable propellants, with Xenon being a typical example. The flow from the ion thruster can be exploited to provide a reactive thrust useful, for instance, to adjust the velocity and/or position of a spacecraft in space. Ion thrusters offer advantages related to the relatively small amounts of consumable propellant fuel that is ionized compared to the large masses of chemical fuel required for combustion-based thrusters. An ion thruster is often built to be small in size, so that the force produced by the ion thruster is small. The ion thruster is therefore operated for a relatively long time. For many missions, ion thrusters are desired to operate for long periods of time that may number into the thousands of hours or more.

Typical ion thruster accelerator grids include two or more separate levels that are at different electrical potentials to create an electric field therebetween. The grid, which is often made of Molybdenum (Mo), is placed just downstream of the ionization chamber. A multiplicity of aligned apertures is in each of the grid levels. Some of the ions accelerated by the applied voltages pass through the apertures, providing the propulsion. Others of the ions impact the grids, heating them and etching away material from them. This causes grid fatigue and distortion, and may ultimately lead to grid failure.

The decay or failure of the accelerator grid can occur so rapidly that it is often the first thruster component to fail and thereby limits the service life of the thruster. Some proposals have been made to increase the service life of accelerator grids. For example, the use of materials of construction other than Mo has been investigated. Carbon (in either fiber or graphite form), beryllium, and titanium have each been investigated. Each of these materials, however, has proven to be less than satisfactory.

One problem with alternative construction materials is that they may exhibit significant deformation as the temperature of the grids changes from the very low ambient temperature of space to the several hundred degrees centigrade operating temperature of the grids. Also, the electron emission property of some materials may result in the establishment of a direct arc between several of the closely spaced grids within the engine. Carbon fibers may also become loose and cause a short circuit. Carbon graphite has proven difficult to engineer, with the result that a graphite grid is relatively thick when compared with a metallic grid and the thruster performance is reduced. For these and other reasons, Mo has remained the material of choice for ion thruster grids.

Other efforts at extending accelerator grid lifetime have focused on varying the conditions of plasma formation in the thruster to limit the damage to the Mo accelerator grids, or to lower the voltage across the grids to lower impact energy of intercepted ions. Generally, however, increases in grid lifetimes gained through these efforts have come only at the expense of ion thruster efficiency and power. Still an additional proposed solution has been to provide a protective surface layer on accelerator grids. To date, however, the proposed layers have not been practical and have been plagued by several problems. For instance, the high operating temperatures and energy of ion impact can cause a high rate of layer disengagement for the underlying grid.

These and other problems remain unresolved in the art.

### DISCLOSURE OF THE INVENTION

An embodiment of the present invention is directed to an ion thruster for accelerating a propellant. An exemplary ion thruster comprises an ionization chamber and at least one accelerator grid proximate to the ionization chamber. In one exemplary embodiment of the invention, the at least one accelerator grid has a thin layer covering at least a portion of its surface that is made of a material that has a molecular weight lower than that of the propellant. Exemplary accelerator grids having these elements have been discovered to provide substantially prolonged service life.

Additional embodiments of the invention are directed to methods for making ion thrusters accelerator grids. One exemplary method includes the steps of forming an accelerator grid core, heating the core to a temperature of at least about 500° C., and of forming a thin layer on the heated accelerator grid core made of a material having a molecular weight of less than about a third the molecular weight of the propellant.

### BRIEF DESCRIPTION OF THE DRAWINGS

FIG. 1 is a schematic of an exemplary ion thruster of the invention;

FIG. 2 is a perspective view of the accelerator grid of FIG. 1;

FIG. 3 is a partial cross section of the accelerator grid of FIG. 2 taken generally along the line 3-3 in the direction indicated;

FIG. 4 is a graph of the results of a SRIM (Stopping and Range of Ions in Matter) calculation of the sputtering yield from a bare molybdenum surface compared to that of a molybdenum surface coated with 0.1 micron of B; and

FIG. 5 is a flow chart illustrating an exemplary method of the invention.

### BEST MODE FOR CARRYING OUT THE INVENTION

In the present invention, an accelerator grid includes a thin protective layer to prevent decay of the grid through sputtering and the like. Before describing exemplary embodiments of the invention in detail, it will be appreciated that the present invention is directed to ion thrusters, accelerator grids for ion thrusters, and to methods for making ion thruster accelerator grids. In describing an accelerator grid of the invention, it will be understood that a method of the invention may also be described. Likewise, when discussing a method of the invention, it will be appreciated that an apparatus of the invention may likewise be had.

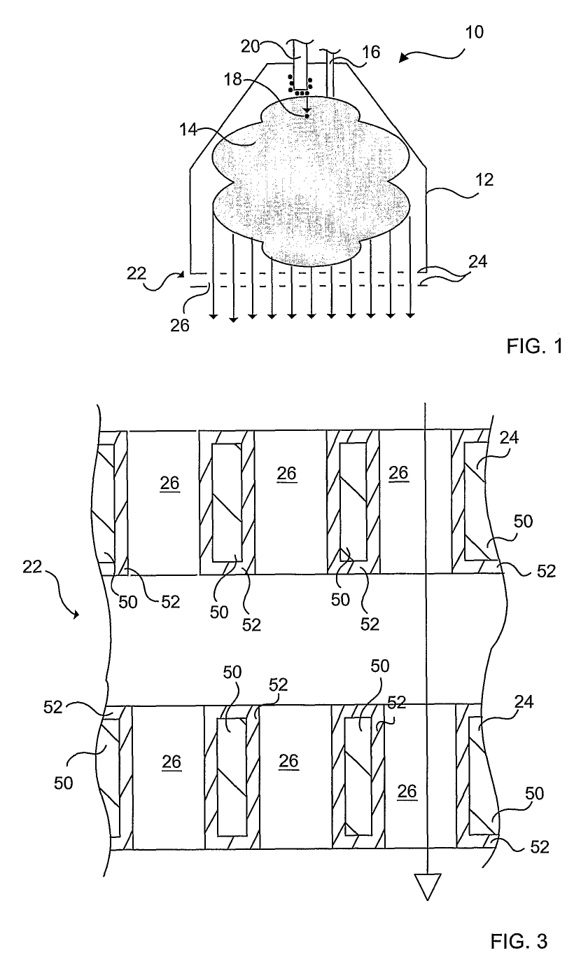

Turning now to the drawings, FIG. 1 is a schematic drawing of an exemplary ion thruster 10 of the invention, which may form, for example, a vehicle engine for a space or other vehicle. The exemplary ion thruster includes an ionization chamber 12 into which propellant 14 is introduced through port 16 from a propellant source (not shown). Once in the chamber 12, the propellant 14 is ionized through bombardment with electrons 18 emitted from a cathode 20. The ionized propellant particles are then drawn out of the ionization chamber 12 by a charged accelerator grids shown generally at 22.

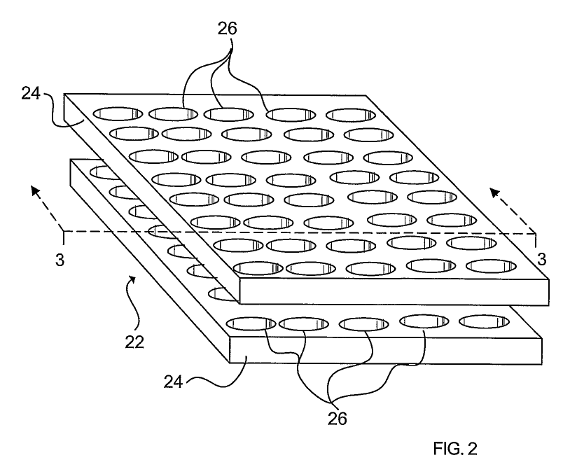

As best shown by the perspective of FIG. 2, the accelerator grid 22 may include two or more individual levels 24, each having a plurality of apertures 26. Although shown in a generally rectangular shape, the accelerator grid levels 24 may be in other shapes as well, including but not limited to an oval or circle. The apertures 26 are shown as being generally circular, but likewise may take other shapes, such as squares or rectangles. Each of the levels 24 is at a different electrical potential to induce an electric field therebetween. The field is sufficient to draw ions from the chamber 12 (FIG. 1) and to accelerate them. Some of the ions pass through the apertures 26 and are ejected from the ion thruster in a rearward direction (in the general direction of the arrows of FIG. 1) to provide an oppositely directed thrust, while others of the ions strike one or the other of the grid levels 24.

FIG. 3 is a cross section of a portion of the accelerator grid 24 taken generally along the line 3-3 of FIG. 2 in the direction indicated by the arrows. Ions pass through the apertures 26 generally along paths such as that illustrated by the arrow of FIG. 3. Each grid level 24 includes a grid core 50 and an overlying cover layer 52. The grid levels 24 are generally less than about 1 mm thick, and are spaced apart from one another by a distance of about 1 mm. Although not evident in the cross section of FIG. 3 (or FIG. 1 or 2), each of the levels 24 preferably has a slightly arcuate or domed surface to provide mechanical strength. An exemplary material of construction for the core 50 is Mo.

A preferred layer 52 covers substantially the entire surface of the grid core 50, and has a thickness that is sufficient to prevent sputtering of the layer 52 under bombardment of incident ions. Put another way, the layer 52 preferably has a thickness that is at least as great as the stopping distance of incident ions. With many typical ion thruster applications, this thickness will often fall between about 0.1 and about 1 micron. The layer 52 also preferably covers substantially the entire surface of the grid core 50, although lesser coverage will also provide benefits and advantages and is contemplated by the present invention. It has been discovered that it is useful to consider sputtering and other decay as it relates to accelerator grids in an analytical framework of “pure” momentum and energy transfer. In this simplified framework, sputtering and decay can be reduced or eliminated by choosing a material of construction for the layer 52 that minimizes efficiency of energy transfer to the layer 52 from incident ions. Generally, efficiency of energy transfer in a collision is highest between two particles of like mass. The efficiency drops off as the masses between the colliding particles become unequal according to the relationship:

$${E}_{LYR} = [ \frac{4 ( {m}_{1} {m}_{2} )}{{( {m}_{1} + {m}_{2} )}^{2}} ] {E}_{INCD} \qquad Eq . 1$$

where m₁ is the molecular weight of the layer 52 material of construction, m₂ is the molecular weight of the propellant, E_{INCD} is the incident energy of the propellant ions that strike the layer, and E_{LYR} is the maximum energy of a target particle after collision. To minimize the energy transfer rate, a large difference in mass between the bombarding and target particles is desired. Since the mass of the propellant is proportional to the thrust delivered by the ion thruster, there are disadvantages to using a lighter propellant.

For these reasons, the preferred layer 52 is made of a material having a molecular weight that is less than that of the propellant, and preferably less than about one third of the propellant. A particular propellant known in the art to be advantageous is Xenon (Xe), which has an atomic mass of 131.3 atomic mass units (amu). Examples of preferred materials of construction for the layer 52 include Carbon (C), Boron (B) and Berrylium (Be), although other materials may also be useful. C and B are generally preferred over Be due to the difficulties in handling that are presented by the toxicity of Be.

Taking C and B by way of example, the mass of C is 12.0 amu and B is 10.8 amu. Plugging these values into Eq. 1 with Xe as the propellant results in E_{LYR} being 0.31 for C and 0.28 for B. Thus a relatively low energy transfer efficiency results between incident Xe particles and the grid layer, and the layer lifetime is substantial. A 1 micron thick layer 52 made of B and/or C on the Mo grid core 50 is believed to increase the lifetime of the grids by as much as a factor of ten.

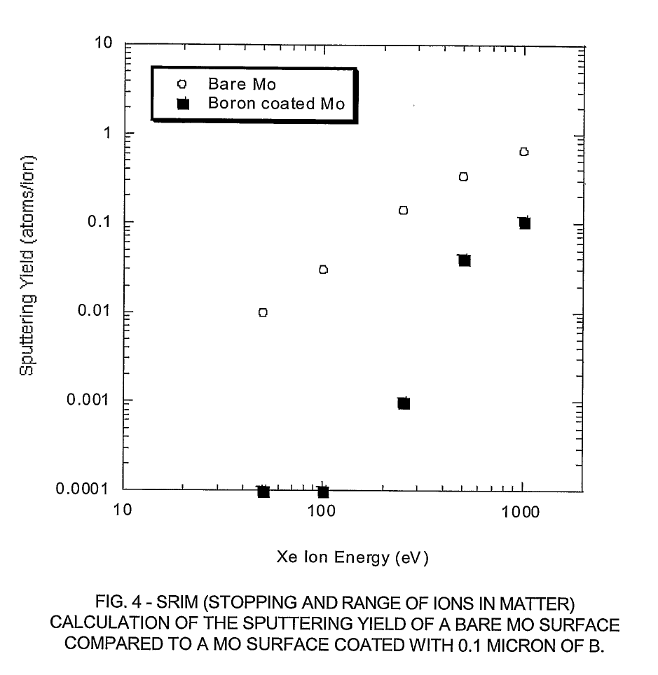

FIG. 4 is a graph of the results of a SRIM (Stopping and Range of Ions in Matter) calculation of the sputtering yield from a bare molybdenum surface compared to that of a molybdenum surface coated with 0.1 micron of B. As can be seen from FIG. 4 the thin B coating acts to protect the underlying Mo from erosion by the incident Xe ions. It is believed that a threshold energy can be passed such that no sputtering occurs. That is, for a given energy of ions striking the grid level 24, and with a sufficiently poor energy transfer between the species, it is not possible for the layer particles to leave the surface because the incident bombardment energy cannot overcome the surface energy barrier. This implies essentially an infinite lifetime for the coated grid components based on sputtering based erosion. This effect is seen for Xe energies below 100 eV incident on the 0.1 micron B layer in FIG. 4.

In addition to being made of a low mass material, the layer 52 is also preferably held to the underlying core 50 with a binding energy that is close to the binding energy of the layer 52 itself. That is, the layer 52 is preferably held to the core 50 with an energy that is not less that the binding energy that holds the layer 52 together. Binding energies of these magnitudes ensure that the layer 52 is not predisposed to disengage from the core 50 under bombardment.

In order to achieve desirable resistance to sputtering and decay, the layer 52 is most preferably crystalline, although amorphous layers 52 may also provide benefits and advantages. Also, particular layer 52 compositions are believed to offer particular advantages. For example, a layer 52 that contains at least about 20% (mole) C is preferred to insure adequate conductivity for operation of the grid 22. Too high a concentration of C, however, in some circumstances may result in lower bonding energy to the underlying core 50 and other undesirable results. Less than about 60% (mole) is preferred. Also, at least about 40% (mole) B is preferred, and at least about 80% (mole) is more preferred. It is believed that these amounts of B are effective to stabilize the layer 52 through interaction with the C. A particular composition believed to be most advantageous is in the range of about 20% (mole) C and about 80% (mole) B.

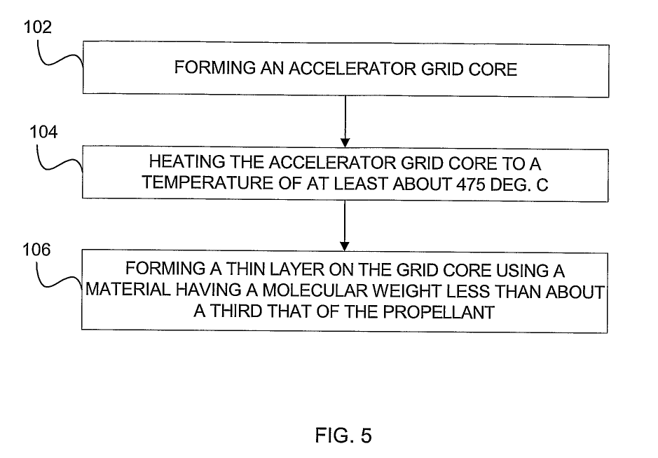

The present invention is also directed to a method for making an accelerator grid for an ion thruster. The flowchart of FIG. 5 illustrates one exemplary method of the invention. An accelerator grid core is first formed (block 102). An exemplary grid core is generally consistent with the core 50 of FIG. 3. It may be made of Mo or other suitable material, and includes a plurality of levels 24 separated from one another. A plurality of apertures 26 is in each of the levels 24 and is generally aligned with one another. Those skilled in the art will appreciate that particular steps for making such a grid core are generally known, and may include, for instance, forming a sheet in the desired overall dimensions of the core levels 24 and then forming the apertures 26 through laser cutting or other suitable method.

The exemplary method of FIG. 4 next includes the steps of heating the core to a temperature of at least about 475° C. (block 104), and more preferably at least about 500° C., and of forming a thin layer on the core using a material having a molecular weight of less than about a third that of the propellant to be used with the accelerator grid (block 106). The thin layer formed on the core is preferably generally consistent with the layer 52. It preferably covers substantially the entire surface of the core 50, and is made of a material such as C, B and/or Be. The preferred composition ranges include at least about 40% (mole) B, more preferably at least about 50% (mole) B, at least about 20% (mole) C, and preferably less than about 60% (mole) C. A most preferred composition is believed to be near about 20% (mole) C and about 80% (mole) B. Preferably, the method of the invention includes a step of providing a crystalline layer 52, although an amorphous layer 52 may also provide benefits and advantages.

Methods of the invention include providing the layer 52 in a thickness sufficient to substantially prevent sputtering of the layer 52, and to thereby protect the grid core 50. As discussed herein above, this thickness may in practice be between about 0.1 and about 1 micron for many applications, although other thicknesses are also contemplated.

It has been discovered that methods of the invention provide particular advantages through steps of binding the layer 52 to the underlying core 50 with a binding energy sufficient to withstand impact energy of bombarding ions. Binding energy of this magnitude sufficiently resists sputtering and other forms of layer decay so as to provide a long service life of the grid core 50. It has been discovered that steps of heating the grid core to a temperature of at least about 475° C., and more preferably at least about 500° C., are beneficial to binding the layer 52 to the core 50 with a suitable binding energy, and/or to forming a crystalline layer 52. It has been discovered that steps of forming a layer on a grid core heated to a temperature of less than about 475° C. result in lower binding energies that suffer a high rate of separation from the grid core in operation. While the preferred minimum temperature of about 500° C. may be related to an extent to the preferred grid material of Mo and the preferred layer composition of at least about 20% (mole) C and at least about 40% (mole) B, it is believed that this temperature may have similar effects for grids and layers made of other materials.

In a most preferred method of the invention, the step of forming the thin layer on the grid is accomplished by exposing the heated grid to plasma. Preferably the method further includes a step of seeding the plasma with a compound containing at least B and C. It has been discovered that a seeding the plasma with a compound such as one or more of carborane (C₂B₁₀H₂), diborane (2(BH₃)) or decaborane (B₁₀H₁₄) and exposing the Mo grid core while at a temperature of at least about 475°-500° C. to the plasma for at least about 1000 seconds results in a layer 52 that has a desirable thickness and composition. Most preferably C₂B₁₀H₂ is used since it contains both C and B.

Likewise, pure B, C or Be films can be applied by using pure plasmas made of those elements. A relatively thin film of 1 micron can be deposited on the grids in about 1000 seconds using this process. Those skilled in the art will appreciate that many methods for preparing and seeding the plasma are known, and include, for example, feeding the seed compound into a noble gas plasma column containing the grid. Most preferably, the plasma column is under vacuum.

While various embodiments of the present invention have been shown and described, it should be understood that other modifications, substitutions and alternatives will be apparent to one of ordinary skill in the art. Such modifications, substitutions and alternatives can be made without departing from the spirit and scope of the invention, which should be determined from the appended claims.

Various features of the invention are set forth in the appended claims.

What is claimed is:

1. An ion thruster for accelerating a propellant, the thruster comprising:
a ionization chamber;
at least one accelerator grid proximate said ionization chamber; and
a layer covering at least a portion of said at least one accelerator grid and made of a material having a molecular weight less than that of the propellant.

2. An ion thruster as defined by claim 1 wherein said material has a molecular weight less than a third that of the propellant.

3. An ion thruster as defined by claim 1 wherein said layer is crystalline.

4. An ion thruster as defined by claim 1 wherein said thin layer has a thickness of between about 0.1 and about 1 micron.

5. An ion thruster as defined by claim 1 wherein the propellant is Xe and said material is one or more of C, B and Be.

6. An ion thruster as defined by claim 1 wherein said layer consists of C and B.

7. An ion thruster as defined by claim 1 wherein said layer comprises at least about 20% (mole) C and at least about 40% (mole) B.

8. An ion thruster as defined by claim 1 wherein said layer is made of between about 20% and about 60% (mole) C.

9. An ion thruster as defined by claim 1 wherein said layer is made of at least about 80% (mole) B.

10. An ion thruster as defined by claim 1 wherein said cover layer has a thickness sufficient to substantially prevent sputtering of said layer when impacted by said propellant.

11. An ion thruster as defined by claim 1 wherein said layer has a thickness that is at least about the stopping distance of the accelerated propellant.

12. An ion thruster as defined by claim 1 wherein said layer is bound to said grid with a binding energy that is at least about the same as the binding energy of said layer.

13. A vehicle engine including the ion thruster as defined by claim 1.

14. An ion thruster as defined by claim 1 wherein the accelerator grid includes a plurality of levels each having a curved surface, and wherein said ionization chamber has an outlet and said accelerator grid is sufficiently proximate said outlet to draw ions from said chamber.

15. An ion thruster as defined by claim 1 wherein said accelerator grid includes a plurality of levels each of which is no greater than about 1 mm thick and includes a plurality of generally aligned holes therethrough.

16. An ion thruster for accelerating a propellant comprising:
an ionization chamber; and,
an accelerator grid proximate said ionization chamber, said grid including a plurality of grid levels each having a multiplicity of holes, each of said levels made of a core layer and a thin cover layer made of a crystalline material that has an atomic weight less than the atomic weight of the propellant.

17. An ion thruster as defined by claim 16 wherein said first material comprises Mo and said second material comprises at least about 20% C and at least about 40% B, and wherein said thin cover layer is between about 0.1 and about 1 micron thick.

18. A method for making an ion thruster accelerator grid useful to accelerate a propellant, the method comprising the steps of:
forming an accelerator grid core;
heating said accelerator grid core to a temperature of at least about 475° C.; and
forming a thin layer on said heated accelerator grid core made of material having a molecular weight of less than about a third the molecular weight of the propellant.

19. A method for making an ion thruster accelerator grid as defined by claim 18 wherein the step of forming a thin layer comprises exposing said accelerator grid core to plasma.

20. A method for making an accelerator grid as defined by claim 19 wherein the step of exposing said accelerator grid to a plasma comprises exposing said accelerator grid to said plasma for at least about 1000 seconds.

21. A method for making an accelerator grid as defined by claim 18 wherein said thin layer includes at least two of C, B and Be, and wherein the method further includes the steps of preparing said plasma by seeding a noble gas working plasma with at least two of C, B and Be.

22. A method for making an accelerator grid as defined by claim 21 wherein said thin layer includes at least about 20% C and at least about 40% B, and wherein the step of seeding said plasma comprises seeding said plasma with a compound containing B and C.

23. A method for making an accelerator grid as defined by claim 18 wherein the step of forming a layer comprises forming a layer of between about 0.1 and about 1 micron thick.

24. A method for making an accelerator grid as defined by claim 18 wherein the step of forming a layer comprises forming a crystalline layer.

25. A method for making an accelerator grid as defined by claim 18 wherein said step of heating said grid core comprises heating said grid core to a temperature of at least about 500° C.

26. A method for making an accelerator grid as defined by claim 18 wherein the step of forming said thin layer further comprises binding said thin layer to said grid with a binding energy that is at least about as great as the binding energy that holds said thin layer together.

27. A method for making an accelerator grid for an ion thruster for ionizing propellant, the method comprising the steps of:
forming a grid core;
forming a thin layer on said grid core and binding said thin layer to said grid core with a binding energy sufficient to resist sputtering of said layer when said layer is exposed to the ionized propellant, said thin layer made of one or more materials that each have a molecular weight less than one third of the propellant.

28. A method for making an accelerator grid as defined by claim 27 wherein said one or more materials include at least about 20% (mol) C and at least about 40% (mol) B.
